(19) United States
(12) Patent Application Publication
(10) Pub. No.: US 2026/0026207 A1
(43) Pub. Date: Jan. 22, 2026

(54) DISPLAY PANEL, ELECTRONIC DEVICE, SPUTTERING DEVICE, AND MANUFACTURING METHOD OF DISPLAY PANEL USING THE SAME

(71) Applicant: Samsung Display Co., Ltd., Yongin-si (KR)

(72) Inventors: DONGMIN LEE, Yongin-si (KR); JOONYONG PARK, Yongin-si (KR); YUNG BIN CHUNG, Yongin-si (KR)

(21) Appl. No.: 19/214,934

(22) Filed: May 21, 2025

(30) Foreign Application Priority Data
Jul. 17, 2024 (KR) 10-2024-0094700
Jan. 6, 2025 (KR) 10-2025-0001744

(51) Int. Cl. H10K 59/123; C23C 14/04; H01J 37/34; H10K 59/12; H10K 59/124; H10K 71/16

(52) U.S. Cl. CPC H10K 59/123; C23C 14/046; H01J 37/3438; H10K 59/1201; H10K 59/124; H10K 71/16; H01J 2237/332

(57) ABSTRACT

Disclosed is a display panel which includes a base layer, a circuit layer on the base layer, and a light emitting element on the circuit layer. The circuit layer includes a transistor, an insulating layer having a contact hole defined therein to expose a portion of the transistor, and a connecting electrode electrically connected with the transistor through the contact hole. An aspect ratio of the contact hole defined as a ratio of a depth of the contact hole to a width of the contact hole is 0.8 or more. The connecting electrode includes a lateral surface portion and an upper surface portion, and a step coverage defined as a ratio of a thickness of the lateral surface portion to a thickness of the upper surface portion is 20% or more. An electronic device including the display panel is also disclosed.

### CROSS-REFERENCE TO RELATED APPLICATIONS

The present application claims priority to and the benefits of Korean Patent Application No. 10-2024-0094700, filed on Jul. 17, 2024, and Korean Patent Application No. 10-2025-0001744, filed on Jan. 6, 2025, in the Korean Intellectual Property Office, the entire content of which is hereby incorporated by reference.

### BACKGROUND

### 1. Field

Embodiments of the present disclosure described herein relate to a display panel, an electronic device, a sputtering device, and a method for manufacturing the display panel using the sputtering device.

### 2. Description of the Related Art

A display module includes a plurality of pixels and drive circuits (e.g., a scan drive circuit and a data drive circuit) that control the plurality of pixels. Each of the plurality of pixels includes a display element and a pixel drive circuit that controls the display element. The pixel drive circuit may include a plurality of transistors in cooperation with one another.

As the size and resolution of the display module gradually increase, the numbers of signal lines and connecting electrodes that connect the display elements and the transistors included in the pixels increase, and the integration of the pixel drive circuits included in the pixels increases.

### SUMMARY

Embodiments of the present disclosure provide a display panel having improved reliability, an electronic device, a sputtering device, and a method for manufacturing the display panel using the sputtering device.

According to an embodiment, a display panel includes a base layer, a circuit layer on the base layer, and a light emitting element on the circuit layer.

The circuit layer includes a transistor on the base layer, an insulating layer (e.g., an electrically insulating layer) that is on the transistor and that has a contact hole defined therein to expose a portion of the transistor, and a connecting electrode electrically connected with the transistor through the contact hole.

An aspect ratio of the contact hole defined as a ratio of a depth of the contact hole to a width of the contact hole is 0.8 or more. The connecting electrode includes a lateral surface portion on a side surface of the insulating layer that defines the contact hole and an upper surface portion on the insulating layer, and a step coverage defined as a ratio of a thickness of the lateral surface portion to a thickness of the upper surface portion is 20% or more.

According to an embodiment, a method for manufacturing a display panel includes forming a circuit layer on a base layer and forming a light emitting element on the circuit layer. The forming the circuit layer includes forming a transistor on the base layer, forming, on the transistor, an insulating layer (e.g., an electrically insulating layer) having a contact hole defined therein to expose a portion of the transistor, and forming a connecting electrode electrically connected with the transistor through the contact hole.

An aspect ratio of the contact hole defined as a ratio of a depth of the contact hole to a width of the contact hole is 0.8 or more. The connecting electrode includes a lateral surface portion on a side surface of the insulating layer that defines the contact hole and an upper surface portion on the insulating layer, and a step coverage defined as a ratio of a thickness of the lateral surface portion to a thickness of the upper surface portion is 20% or more.

According to an embodiment, a sputtering device for forming a thin metal film on a target substrate having a contact hole defined therein includes a deposition chamber that provides a deposition space, a support substrate that supports the target substrate within the deposition space, a plasma electrode that faces the target substrate within the deposition space, a source target fixed to the plasma electrode, and a power supply unit that supplies high power to the plasma electrode.

An aspect ratio of the contact hole defined as a ratio of a depth of the contact hole to a width of the contact hole is 0.8 or more. The thin metal film includes a lateral surface portion on a side surface of an insulating layer (e.g., an electrically insulating layer) that defines the contact hole and an upper surface portion on the insulating layer, and a step coverage defined as a ratio of a thickness of the lateral surface portion to a thickness of the upper surface portion is 20% or more.

### BRIEF DESCRIPTION OF THE DRAWINGS

The above and other objects and features of embodiments of the present disclosure will become apparent by describing in more detail embodiments thereof with reference to the accompanying drawings.

FIG. 1 is a perspective view illustrating an electronic device according to an embodiment of the present disclosure.

FIG. 2 is an exploded perspective view of the electronic device according to an embodiment of the present disclosure.

FIG. 3 is a cross-sectional view of a display module according to an embodiment of the present disclosure.

FIG. 4 is a plan view of a display panel according to an embodiment of the present disclosure.

FIG. 5 is a view illustrating an equivalent circuit of a pixel according to an embodiment of the present disclosure.

FIG. 6 is a cross-sectional view of the display panel according to an embodiment of the present disclosure.

FIGS. 7A and 7B are views illustrating a sputtering device according to embodiments of the present disclosure.

FIG. 8 is a view illustrating an emission form of metal ions according to an embodiment of the present disclosure.

FIG. 9 is an enlarged cross-sectional view illustrating a contact hole portion of the display panel according to an embodiment of the present disclosure.

FIGS. 10A to 10E are cross-sectional views illustrating a process of manufacturing the display panel according to an embodiment of the present disclosure.

FIG. 11 is a graph depicting the reflectance of a thin metal film according to an embodiment of the present disclosure.

FIG. 12 is a block diagram of an electronic device according to an embodiment of the present disclosure.

FIG. 13 illustrates schematic views of electronic devices according to various embodiments.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. In the drawings, the thicknesses, proportions, and dimensions of components may be exaggerated for effective description. As used herein, the term “and/or” includes all of one or more combinations defined by related components.

Terms such as first, second, and the like may be used to describe various components, but the components should not be limited by the terms. The terms may be used only for distinguishing one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

In embodiments, terms such as “below”, “under”, “above”, and “over” are used to describe a relationship between components illustrated in the drawings. The terms are relative concepts and are described based on directions illustrated in the drawings.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

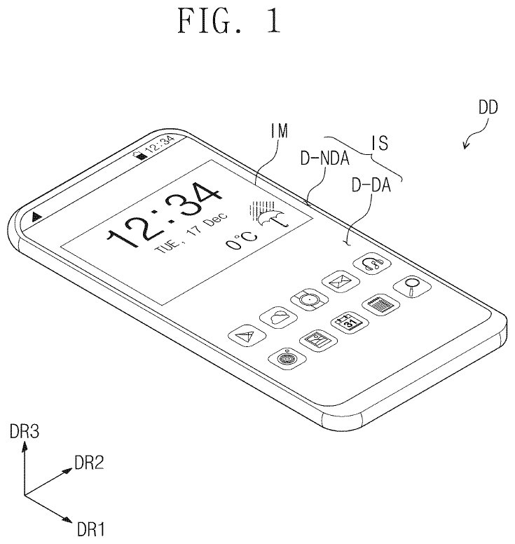

FIG. 1 is a perspective view of an electronic device according to an embodiment of the present disclosure.

The electronic device DD of an embodiment may be a display device that is activated in response to an electrical signal and that displays an image IM. The electronic device DD may be a display device employed in a television, a monitor, a billboard, a tablet computer, a car navigation unit, a personal computer, a notebook computer, a personal digital terminal, a game machine, a smart phone, a camera, and a wearable device. For example, the wearable device may include a virtual reality device, an augmented reality device, and a smart watch. The virtual reality device and the augmented reality device may be devices in the form of eyeglasses that are able to be worn by a user. The embodiments of the electronic device DD are illustrated as an example, and the electronic device DD is not limited to any one embodiment as long as it does not depart from the spirit and scope of the present disclosure.

Referring to FIG. 1, when viewed from above a plane, the electronic device DD may have a rectangular shape having long sides that extend in a first direction DR1 and short sides that extend in a second direction DR2. However, without being limited thereto, the electronic device DD, when viewed from above the plane, may have various suitable shapes such as a circular shape (e.g., a generally circular shape) or a polygonal shape rather than a rectangular shape.

The electronic device DD may display the image IM in a third direction DR3 through a display surface IS parallel (e.g., substantially parallel) to a plane defined by the first direction DR1 and the second direction DR2. The third direction DR3 may be substantially parallel to the normal direction of the display surface IS. The display surface IS on which the image IM is displayed may correspond to the front surface of the electronic device DD. The image IM may include a still image as well as a dynamic image. In FIG. 1, icon images are illustrated as an example of the image IM.

FIG. 1 illustrates the electronic device DD having the flat display surface IS. However, without being limited thereto, the display surface IS of the electronic device DD may further include a curved surface bent from the flat surface.

In this embodiment, front surfaces (or, upper surfaces) and rear surfaces (or, lower surfaces) of members constituting the electronic device DD may be defined based on the third direction DR3. The front surfaces and the rear surfaces may be opposite each other in the third direction DR3, and the normal directions of the front surfaces and the rear surfaces may be parallel (e.g., substantially parallel) to the third direction DR3. The separation distances between the front surfaces and the rear surfaces defined in the third direction DR3 may correspond to the thicknesses of the members.

The expression “when viewed from above the plane” used herein may mean that it is viewed in the third direction DR3. The expression “on a cross-section” used herein may mean that it is viewed in the first direction DR1 or the second direction DR2. However, the directions indicated by the first to third directions DR1, DR2, and DR3 may be relative concepts and may be changed to other directions.

The electronic device DD may be a flexible electronic device. The term “flexible” used herein may mean a property of being bent (e.g., capable of being bent) and may include everything from a structure capable of being fully folded to a structure capable of being bent to a level of several nanometers. For example, the flexible electronic device DD may include a curved device, a rollable device, a slidable device, and/or a foldable device. However, without being limited thereto, the electronic device DD may be a rigid electronic device.

The display surface IS of the electronic device DD may include a display portion D-DA and a non-display portion D-NDA. The display portion D-DA may be a portion where the image IM is displayed on the front surface of the electronic device DD, and the user may visually recognize the image IM through the display portion D-DA. Although FIG. 1 illustrates the display portion D-DA having a quadrangular shape when viewed from above the plane, the shape of the display portion D-DA may be changed in various suitable ways depending on the design of the electronic device DD.

The non-display portion D-NDA may be a portion where the image IM is not displayed on the front surface of the electronic device DD. The non-display portion D-NDA may be a portion that has a set or certain color and blocks light (or reduces transmission of light). The non-display portion D-NDA may be adjacent to the display portion D-DA. For example, the non-display portion D-NDA may be provided outside the display portion D-DA and may be around (e.g., surround) the display portion D-DA. However, this is illustrated as an example, and the non-display portion D-NDA may be adjacent to only one side of the display portion D-DA or may be on a side surface rather than the front surface of the electronic device DD. Without being limited thereto, the non-display portion D-NDA may be omitted.

The electronic device DD may sense an external input applied from the outside. The external input may have various suitable forms such as pressure, temperature, light, and/or the like that are provided from the outside. The external input may include not only an input making contact with the electronic device DD (e.g., contact by the user's or a pen) but also an input (e.g., hovering) applied in proximity to the electronic device DD.

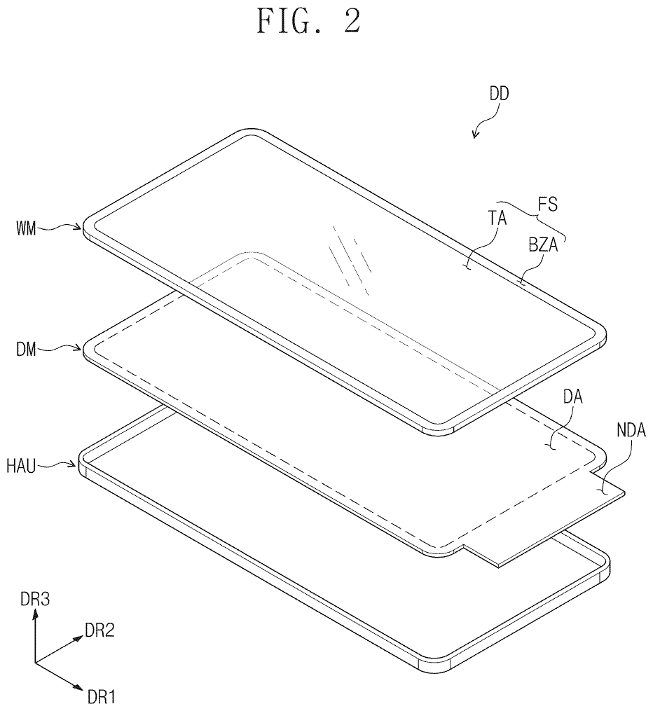

FIG. 2 is an exploded perspective view of the electronic device DD according to an embodiment of the present disclosure.

Referring to FIG. 2, the electronic device DD may include a window WM, a display module DM, and a housing HAU.

The window WM and the housing HAU may be coupled to form the exterior of the electronic device DD and may provide an inner space in which components of the electronic device DD, such as the display module DM, are accommodated.

The window WM may be on the display module DM. The window WM may protect the display module DM from external impact. The front surface of the window WM may correspond to the above-described display surface IS (refer to FIG. 1) of the electronic device DD. The front surface FS of the window WM may include a transmissive area TA and a bezel area BZA.

The transmissive area TA of the window WM may be an optically clear area. The window WM may transmit an image provided by the display module DM through the transmissive area TA, and the user may visually recognize the corresponding image. The transmissive area TA may correspond to the above-described display portion D-DA (refer to FIG. 1) of the electronic device DD.

The window WM may include an optically clear insulating material (e.g., an optically clear electrically insulating material). For example, the window WM may include glass, sapphire, and/or plastic. The window WM may have a single-layer structure or a multi-layer structure. The window WM may further include functional layers, such as an anti-fingerprint layer, a phase control layer, and/or a hard coating layer, which are on an optically clear substrate.

The bezel area BZA of the window WM may be an area provided by depositing and/or printing a material having a set or certain color on the transparent substrate and/or by coating the transparent substrate with the material. The bezel area BZA of the window WM may prevent a component of the display module DM that overlaps the bezel area BZA from being visible from the outside (or may reduce a visibility thereof). The bezel area BZA may correspond to the above-described non-display portion D-NDA (refer to FIG. 1) of the electronic device DD.

The display module DM may be between the window WM and the housing HAU. The display module DM may display an image in response to an electrical signal. The display module DM may include a display area DA and a non-display area NDA adjacent to the display area DA.

The display area DA may be an area that is activated in response to an electrical signal and that outputs an image. The display area DA of the display module DM may overlap the transmissive area TA of the window WM. In embodiments, the expression “one area/portion overlaps another area/portion” used herein is not limited to having the same area and/or shape. An image output from the display area DA may be visible from the outside through the transmissive area TA.

The non-display area NDA may be adjacent to the display area DA. For example, the non-display area NDA may be around (e.g., surround) the display area DA. However, without being limited thereto, the non-display area NDA may be defined in various suitable shapes. The non-display area NDA may be an area where a drive circuit to drive elements provided in the display area DA, signal lines that provide electrical signals to the elements, and pads are provided. The non-display area NDA of the display module DM may overlap the bezel area BZA of the window WM, and the bezel area BZA may prevent components provided in the non-display area NDA from being visible from the outside (or may reduce a visibility thereof).

The housing HAU may be under the display module DM and may accommodate the display module DM. The housing HAU may protect the display module DM by absorbing impact applied to the display module DM from the outside and preventing or reducing infiltration of foreign matter/moisture into the display module DM. In an embodiment, the housing HAU may be implemented in a form in which a plurality of receiving members are coupled.

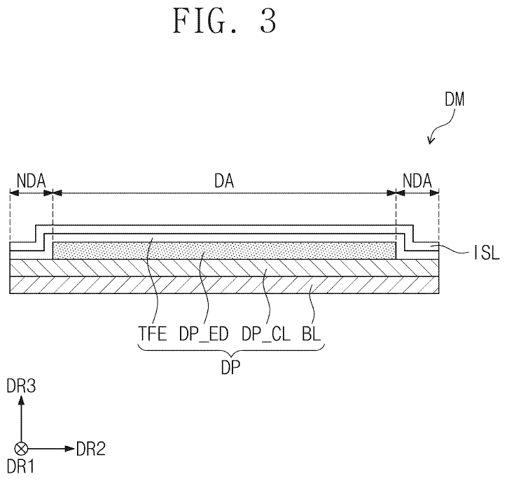

FIG. 3 is a cross-sectional view of the display module according to an embodiment of the present disclosure.

Referring to FIG. 3, the display module DM includes a display panel DP and an input sensor layer ISL.

The display panel DP may be a component that substantially generates an image. The display panel DP may be an emissive display panel. For example, the display panel DP may be an organic light emitting display panel, an inorganic light emitting display panel, a micro-LED display panel, or a nano-LED display panel. The display panel DP may be referred to as a display layer.

The display panel DP may include a base layer BL, a circuit layer DP_CL, a light emitting element layer DP_ED, and an encapsulation layer TFE.

The base layer BL may be a member that provides a base surface on which the circuit layer DP_CL is provided. The base layer BL may be a rigid substrate or may be a flexible substrate capable of being bent, folded, and/or rolled. The base layer BL may be a glass substrate, a metal substrate, and/or a polymer substrate. However, embodiments of the present disclosure are not limited thereto, and the base layer BL may include an inorganic layer, an organic layer, or a composite layer including an inorganic layer and an organic layer.

The base layer BL may have a multi-layer structure. For example, the base layer BL may include a first synthetic resin layer, an inorganic layer having a multi-layer structure or a single-layer structure, and a second synthetic resin layer on the inorganic layer. Each of the first synthetic resin layer and the second synthetic resin layer may include a polyimide-based resin, but is not particularly limited.

The circuit layer DP_CL may be on the base layer BL. The circuit layer DP_CL may include an insulating layer (e.g., an electrically insulating layer), a semiconductor pattern, a conductive pattern (e.g., an electrically conductive pattern), and a signal line.

The light emitting element layer DP_ED may be on the circuit layer DP_CL. The light emitting element layer DP_ED may include a light emitting element. For example, the light emitting element may include an organic LED, an inorganic LED, an organic-inorganic LED, a quantum dot, a quantum rod, a micro-LED, and/or a nano-LED.

The encapsulation layer TFE may be on the light emitting element layer DP_ED. The encapsulation layer TFE may protect the light emitting element layer DP_ED from foreign matter such as moisture, oxygen, and dust particles. The encapsulation layer TFE may include at least one inorganic layer. The encapsulation layer TFE may include a stacked structure of an inorganic layer/an organic layer/an inorganic layer.

The input sensor layer ISL may be on the display panel DP. The input sensor layer ISL may sense an external input applied from the outside. The external input may be a user input. The user input may include various suitable types (or kinds) of external inputs such as a part of the user's body, light, heat, a pen, and/or pressure.

The input sensor layer ISL may be formed on the display panel DP through a continuous process. In embodiments, the input sensor layer ISL may be directly provided on the display panel DP (for example, the encapsulation layer TFE). The expression “directly provided” used herein may mean that a third component (e.g., an adhesive member) is not between the input sensor layer ISL and the display panel DP. For example, a separate adhesive member may not be between the input sensor layer ISL and the display panel DP.

The window WM (refer to FIG. 2) may be on the input sensor layer ISL. In embodiments, a functional layer may be between the input sensor layer ISL and the window WM. The functional layer may include an anti-reflective layer that decreases the reflectance of external light incident from outside the electronic device DD (refer to FIG. 2).

The anti-reflective layer may include color filters. The color filters may have a set or certain arrangement. For example, the color filters may be provided in consideration of the colors of light emitted by pixels included in the display panel DP. In embodiments, the anti-reflective layer may further include a black matrix adjacent to the color filters.

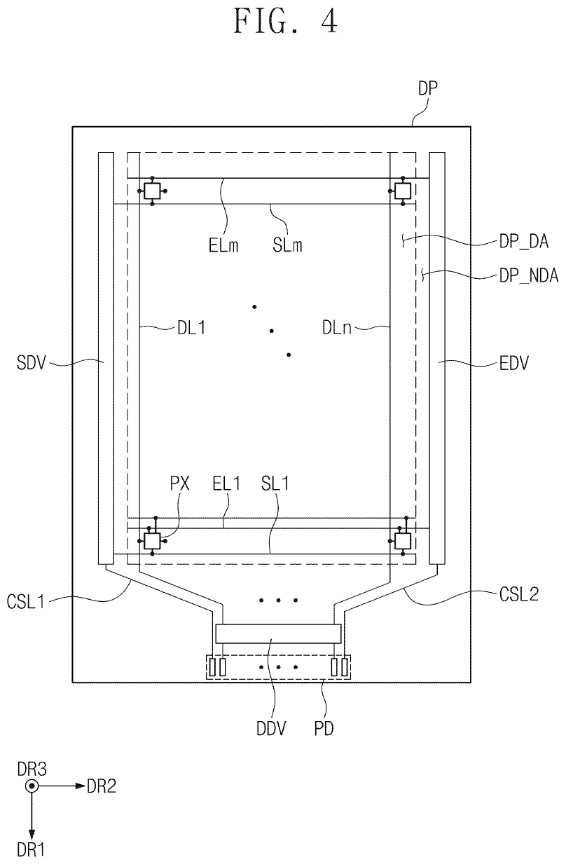

FIG. 4 is a plan view of the display panel according to an embodiment of the present disclosure.

Referring to FIG. 4, the display panel DP may include a scan driver SDV, a data driver DDV, an emission driver EDV, and a plurality of pads PD. The display panel DP may have a rectangular shape having short sides that extend in the second direction DR2 and long sides that extend in the first direction DR1. However, the shape of the display panel DP is not limited thereto. The display panel DP may include a display area DP_DA and a non-display area DP_NDA around (e.g., surrounding) the display area DP_DA.

The display panel DP may include a plurality of pixels PX, a plurality of scan lines SL1 to SLm, a plurality of data lines DL1 to DLn, a plurality of emission control lines EL1 to ELm, a first control line CSL1, and a second control line CSL2. “m” and “n” are natural numbers.

The pixels PX may be provided in the display area DP_DA. The scan driver SDV and the emission driver EDV may be provided in the non-display areas DP_NDA adjacent to the long sides of the display panel DP, respectively. The data driver DDV may be in the non-display area NDA adjacent to one of the short sides of the display panel DP. The data driver DDV may be adjacent to the lower end of the display panel DP when viewed from above the plane.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The emission control lines EL1 to ELm may extend in the second direction DR2 and may be connected to the pixels PX and the emission driver EDV.

The first control line CSL1 may be connected to the scan driver SDV and may extend toward the lower end of the display panel DP. The second control line CSL2 may be connected to the emission driver EDV and may extend toward the lower end of the display panel DP. The data driver DDV may be between the first control line CSL1 and the second control line CSL2.

The pads PD may be provided in the non-display area NDA adjacent to the lower end of the display panel DP and may be closer to the lower end of the display panel DP than the data driver DDV. The data driver DDV, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

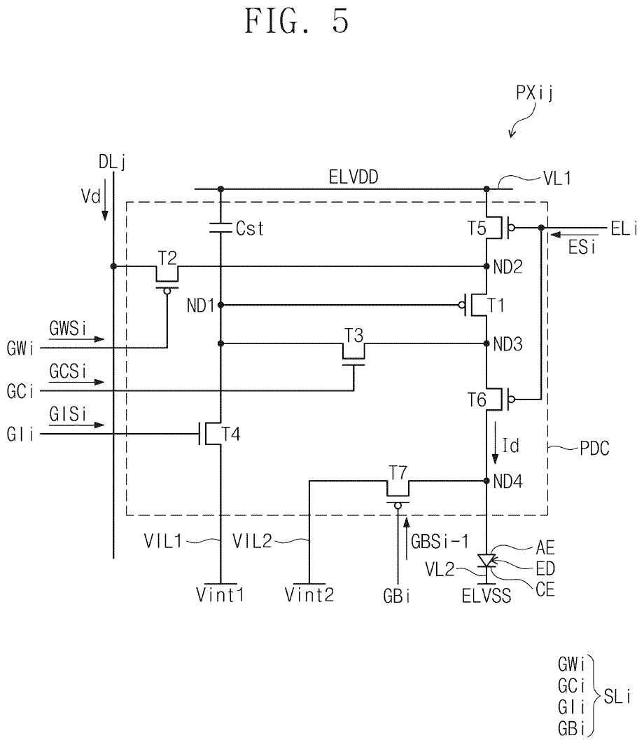

In embodiments, the electronic device DD may further include a drive controller to control operations of the scan driver SDV, the data driver DDV, and the emission driver EDV and a voltage generator to generate a first drive voltage ELVDD and a second drive voltage ELVSS (refer to FIG. 5). The drive controller and the voltage generator may be electrically connected to the data driver DDV, the scan driver SDV, the emission driver EDV, and the pixels PX through the pads PD.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission control signals, and the emission control signals may be applied to the pixels PX through the emission control lines EL1 to ELm.

The pixels PX may receive the data voltages in response to the scan signals. The pixels PX may display an image by emitting light having luminance corresponding to the data voltages in response to the emission control signals.

FIG. 5 is a view illustrating an equivalent circuit of a pixel according to an embodiment of the present disclosure. FIG. 5 illustrates a pixel PXij connected to the i-th scan line SLi, the i-th emission control line ELi, and the j-th data line DLj. In embodiments, “i” and “j” are natural numbers.

Referring to FIG. 5, the pixel PXij may include a light emitting element ED and a pixel drive circuit PDC electrically connected to the light emitting element ED. The pixel drive circuit PDC may include transistors T1 to T7 and a capacitor Cst. The transistors T1 to T7 and the capacitor Cst may control the amount of current flowing through the light emitting element ED, and the light emitting element ED may generate light having a set or certain luminance depending on the amount of current provided thereto.

The i-th scan line SLi may include first to fourth scan lines GWi, GCi, GIi, and GBi. The first scan line GWi may receive the i-th write scan signal GWSi and may be referred to as the i-th write scan line GWi. The second scan line GCi may receive the i-th compensation scan signal GCSi and may be referred to as the i-th compensation scan line GCi. The third scan line GIi may receive the i-th initialization scan signal GISi and may be referred to as the i-th initialization scan line GIi. The fourth scan line GBi may receive the i-th black scan signal GBSi and may be referred to as the i-th black scan line GBi. However, without being limited thereto, the fourth scan line GBi may be referred to as the (i−1)th write scan line that is a write scan line prior to the i-th write scan line GWi.

The transistors T1 to T7 may include the first to seventh transistors T1 to T7. Each of the first to seventh transistors T1 to T7 may include a source electrode, a drain electrode, and a gate electrode. Hereinafter, the source electrode, the drain electrode, and the gate electrode may be referred to as the source, the drain, and the gate, respectively.

In embodiments, the expression “electrically connected between a transistor and a signal line or between a transistor and a transistor” used herein means that an electrode of the transistor has a one-body shape with the signal line or is connected with the signal line through a connecting electrode.

The first to seventh transistors T1 to T7 may be transistors having an oxide semiconductor layer or transistors having a low-temperature polycrystalline silicon (LTPS) semiconductor layer. The first to seventh transistors T1 to T7 may be N-type transistors or P-type transistors. For example, the first transistor T1, the second transistor T2, the fifth transistor T5, the sixth transistor T6, and the seventh transistor T7 may be PMOS transistors having an LTPS semiconductor layer, and the third transistor T3 and the fourth transistor T4 may be NMOS transistors having an oxide semiconductor layer. However, embodiments of the transistors T1 to T7 are not limited thereto. Furthermore, although the pixel drive circuit PDC including the seven transistors T1 to T7 is illustrated as an example, the number of transistors included in the pixel drive circuit PDC is not limited thereto and may be any suitable number.

The light emitting element ED may be defined as an organic light emitting element. The light emitting element ED may include a first electrode AE and a second electrode CE. For example, the first electrode AE may be an anode, and the second electrode CE may be a cathode. The first electrode AE of the light emitting element ED may be electrically connected to a first voltage line VL1 that receives the first drive voltage ELVDD. The second electrode CE of the light emitting element ED may be electrically connected to a second voltage line VL2 that receives the second drive voltage ELVSS.

The first transistor T1 may be electrically connected between the first voltage line VL1 that receives the first drive voltage ELVDD and the light emitting element ED. The first transistor T1 may include a source connected to a second node ND2, a drain connected to a third node ND3, and a gate connected to a first node ND1. The first transistor T1 may be turned on by a voltage of the first node ND1. The first transistor T1 may receive a data voltage Vd transferred by the j-th data line DLj depending on a switching operation of the second transistor T2 and may supply a drive current Id to the light emitting element ED. In this embodiment, the first transistor T1 may be defined as a drive transistor.

The second transistor T2 may be electrically connected between the j-th data line DLj and the first transistor T1. The second transistor T2 may include a source connected to the j-th data line DLj, a drain connected to the second node ND2, and a gate connected to the first scan line GWi. The second transistor T2 and the first transistor T1 may be connected through the second node ND2. The second transistor T2 may be turned on by the write scan signal GWSi applied through the first scan line GWi. The data voltage Vd applied to the j-th data line DLj may be transferred to the source of the first transistor T1 by the turned-on second transistor T2. In this embodiment, the second transistor T2 may be defined as a switching transistor.

The third transistor T3 may be electrically connected between the fourth transistor T4 and the first transistor T1. The third transistor T3 may include a source connected to the first node ND1, a drain connected to the third node ND3, and a gate connected to the second scan line GCi. The third transistor T3 and the first transistor T1 may be connected through the third node ND3. The third transistor T3 may be turned on by the compensation scan signal GCSi applied through the second scan line GCi. The gate of the first transistor T1 and the drain of the first transistor T1 may be electrically connected with each other by the turned-on third transistor T3, and the first transistor T1 may be diode-connected. In this embodiment, the third transistor T3 may be defined as a compensation transistor.

The fourth transistor T4 may be electrically connected between a first initialization voltage line VIL1 that receives a first initialization voltage Vint1 and the third transistor T3. The fourth transistor T4 may include a source connected to the first initialization voltage line VIL1, a drain connected to the first node ND1, and a gate connected to the third scan line GIi. The fourth transistor T4 may be turned on by the initialization scan signal GISi applied through the third scan line GIi. The first initialization voltage Vint1 may be transferred to the first node ND1 by the turned-on fourth transistor T4, and the potential of the gate of the first transistor T1 may be initialized. In this embodiment, the fourth transistor T4 may be defined as an initialization transistor.

The fifth transistor T5 may be electrically connected between the first voltage line VL1 that receives the first drive voltage ELVDD and the first transistor T1. The fifth transistor T5 may include a source connected to the first voltage line VL1, a drain connected to the second node ND2, and a gate connected to the emission line ELi.

The sixth transistor T6 may be electrically connected between the first transistor T1 and the light emitting element ED. The sixth transistor T6 may include a source connected to the third node ND3, a drain connected to the first electrode AE of the light emitting element ED through a fourth node ND4, and a gate connected to the emission line ELi.

The fifth transistor T5 and the sixth transistor T6 may be turned on by an emission control signal ESi applied through the emission control line ELi. The light emission time of the light emitting element ED may be controlled by the emission control signal ESi. When the fifth transistor T5 and the sixth transistor T6 are turned on, the drive current Id depending on a voltage difference between the gate voltage of the gate of the first transistor T1 and the first drive voltage ELVDD may be generated. The drive current Id may be supplied to the light emitting element ED through the sixth transistor T6, and the light emitting element ED may emit light. In this embodiment, the fifth transistor T5 and the sixth transistor T6 may be defined as emission control transistors.

The seventh transistor T7 may be electrically connected between the sixth transistor T6 and a second initialization voltage line VIL2 that receives a second initialization voltage Vint2. The seventh transistor T7 may include a source connected to the fourth node ND4, a drain connected to the second initialization voltage line VIL2, and a gate connected to the fourth scan line GBi.

The seventh transistor T7 may be turned on by the i-th black scan signal GBSi applied through the fourth scan line GBi. The second initialization voltage Vint2 may be transferred to the fourth node ND4 by the turned-on seventh transistor T7. The second initialization voltage Vint2 may have the same or substantially the same level as the first initialization voltage Vint1. However, without being limited thereto, the second initialization voltage Vint2 may have a level different from the level of the first initialization voltage Vint1. In this embodiment, the seventh transistor T7 may be defined as an initialization transistor.

The seventh transistor T7 may improve the ability of the pixel PXij to express black. A portion of the drive current Id may escape through the seventh transistor T7 as a bypass current. When a black image is displayed, a current obtained by subtracting the amount of the bypass current escaping through the seventh transistor T7 from the drive current Id may be provided to the light emitting element ED, and thus the black image may be clearly displayed. For example, accurate black luminance image may be implemented through the seventh transistor T7, and thus the contrast ratio of the electronic device DD (refer to FIG. 1) may be improved.

The capacitor Cst may include a first electrode that receives the first drive voltage ELVDD and a second electrode connected to the first node ND1. Charges corresponding to a voltage difference between the first electrode and the second electrode may be stored in the capacitor Cst. When the fifth transistor T5 and the sixth transistor T6 are turned on, the amount of current flowing through the first transistor T1 may be determined depending on the voltage stored in the capacitor Cst.

The configuration of the pixel drive circuit PDC illustrated in FIG. 5 is illustrated as an example, and without being limited thereto, various suitable changes and modifications may be made to the configuration of the pixel drive circuit PDC.

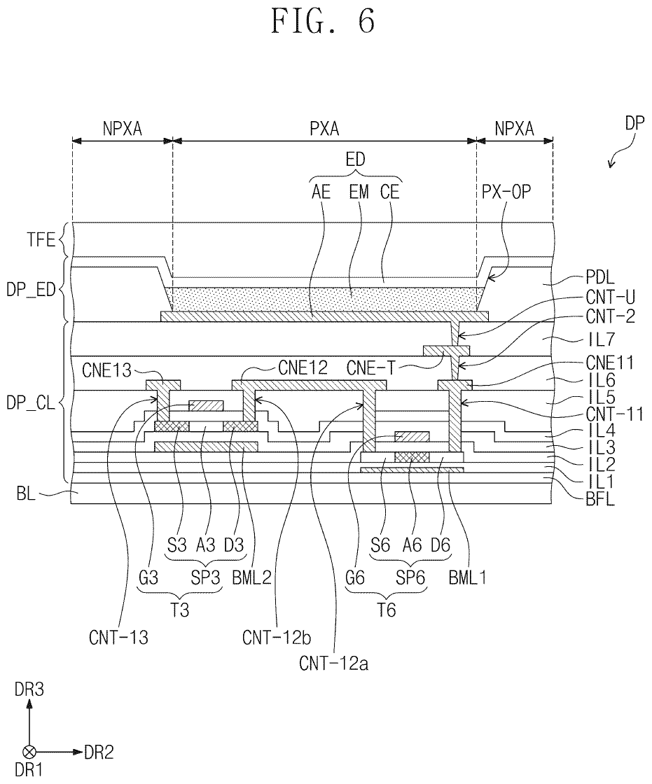

FIG. 6 is a cross-sectional view of the display panel according to an embodiment of the present disclosure. FIG. 6 illustrates the light emitting element ED and some transistors T3 and T6 of the pixel drive circuit PDC (refer to FIG. 5) connected to the light emitting element ED. The above description may be applied to the components of the display panel DP illustrated in FIG. 6.

Referring to FIG. 6, the display panel DP may include the base layer BL, the circuit layer DP_CL, the light emitting element layer DP_ED, and the encapsulation layer TFE.

The base layer BL may provide a base surface on which the circuit layer DP_CL is provided. The circuit layer DP_CL may include insulating layers (e.g., electrically insulating layers) BFL and IL1 to IL7, the transistors T3 and T6, and connecting electrodes CNE11 to CNE13 and CNE-T. The insulating layers BFL and IL1 to IL7 may include the buffer layer BFL and the first to seventh insulating layers (e.g., electrically insulating layers) IL1 to IL7 on the buffer layer BFL. However, insulating layers (e.g., electrically insulating layers) included in the circuit layer DP_CL are not limited thereto and may suitably vary depending on the configuration of the pixel drive circuit included in the circuit layer DP_CL and a process of the circuit layer DP_CL.

The buffer layer BFL may be on the base layer BL. The buffer layer BF may include at least one inorganic layer. For example, the buffer layer BFL may include at least one selected from aluminum oxide, titanium oxide, silicon oxide, silicon nitride, silicon oxy nitride, zirconium oxide, and hafnium oxide. The buffer layer BFL may improve the coupling force between the base layer BL and a semiconductor pattern layer (e.g., the sixth semiconductor pattern SP6) or a conductive pattern layer (e.g., an electrically conductive pattern layer) of the circuit layer DP_CL on the base layer BL.

Each of the first to seventh insulating layers IL1 to IL7 may include an inorganic layer and/or an organic layer and may have a single-layer structure or a multi-layer structure. The inorganic layer may include at least one selected from aluminum oxide, titanium oxide, silicon oxide, silicon nitride, silicon oxy nitride, zirconium oxide, and hafnium oxide. However, the material of the inorganic layer is not limited thereto. The organic layer may include at least one selected from an acrylic resin, a methacrylic resin, a polyisoprene resin, a vinyl resin, an epoxy resin, a urethane-based resin, a celluosic resin, a siloxane-based resin, a polyamide resin, and a perylene-based resin. However, the material of the organic layer is not limited thereto.

A first light blocking pattern BML1 may be on the buffer layer BFL. The first light blocking pattern BML1 may be directly on the base layer BL when the buffer layer BFL is omitted. The first light blocking pattern BML1 may include molybdenum. The first light blocking pattern BML1 may perform a shielding function. The first light blocking pattern BML1 may block electric potential due to polarization between the insulating layers IL1 to IL7 on the first light blocking pattern BML1 from affecting the transistors T1 to T7 (refer to FIG. 5), or may reduce an effect thereof.

The sixth semiconductor pattern SP6 may be on the first insulating layer IL1. The sixth semiconductor pattern SP6 may include a silicon semiconductor. For example, the sixth semiconductor pattern SP6 may include poly silicon or amorphous silicon. However, a material included in the sixth semiconductor pattern SP6 is not limited thereto as long as the sixth semiconductor pattern SP6 has a semiconductor property.

The sixth semiconductor pattern SP6 may include a plurality of areas having different electrical properties depending on whether doping is performed or not. The first semiconductor pattern layer may include a first area having a high conductivity (e.g., electrical conductivity) and a second area having a low conductivity (e.g., electrical conductivity). The first area may be doped with an N-type dopant or a P-type dopant. A P-type transistor may include a doped area doped with a P-type dopant, and an N-type transistor may include a doped area doped with an N-type dopant. The second area may be an un-doped area or may be an area more lightly doped than the first area.

The first area may have a higher conductivity (e.g., electrical conductivity) than the second area and may substantially serve as a source or drain of a transistor. The second area may substantially correspond to a channel (or, an active) of the transistor. For example, the first area of the first semiconductor pattern layer having a high conductivity (e.g., electrical conductivity) may be the source or drain of the transistor or a connecting signal line, and the second area having a low conductivity (e.g., electrical conductivity) may be the channel of the transistor.

The sixth semiconductor pattern SP6 may include the sixth source S6, the sixth channel A6, and the sixth drain D6. The sixth source S6 and the sixth drain D6 may extend from the sixth channel A6 in opposite directions. In embodiments, the sixth source S6 and the sixth drain D6 may be spaced apart from each other with the sixth channel A6 therebetween when viewed from above the plane.

The first insulating layer IL1 may be on the buffer layer BFL. The first insulating layer IL1 may cover the first light blocking pattern BML1. The second insulating layer IL2 may be on the first insulating layer IL1. The second insulating layer IL2 may cover the sixth semiconductor pattern SP6.

The sixth gate electrode G6 may be on the second insulating layer IL2. The sixth gate electrode G6 may overlap the sixth channel A6. In an embodiment, the sixth gate electrode G6 may function as a mask in a process of doping the sixth semiconductor pattern SP6.

Although FIG. 6 illustrates an example that the sixth transistor T6 has a top-gate structure in which the sixth gate electrode G6 is provided over the sixth semiconductor pattern SP6, embodiments are not limited thereto, and the sixth transistor T6 has a bottom-gate structure in which the sixth gate electrode G6 of the sixth transistor T6 is provided under the sixth semiconductor pattern SP6.

In embodiments, the first transistor T1, the second transistor T2, the fifth transistor T5, and the seventh transistor T7 (refer to FIG. 5) described above may be transistors having the same or substantially the same structure as the sixth transistor T6. For example, the semiconductor patterns of the first transistor T1, the second transistor T2, the fifth transistor T5, and the seventh transistor T7 (refer to FIG. 5) may be formed from the first semiconductor pattern layer in the same or substantially the same manner as the sixth semiconductor pattern SP6, and the gate electrodes of the first transistor T1, the second transistor T2, the fifth transistor T5, and the seventh transistor T7 (refer to FIG. 5) may be formed from the same conductive pattern layer (e.g., electrically conductive pattern layer) as the sixth gate electrode G6. However, embodiments are not necessarily limited thereto.

A second light blocking pattern BML2 may be further on the second insulating layer IL2. The second light blocking pattern BML2 may include the same or substantially the same material as the first light blocking pattern BML1. The first light blocking pattern BML1 may correspond to a part of the above-described first to third scan lines GWi, GCi, and GIi (refer to FIG. 5).

The third insulating layer IL3 may be on the second insulating layer IL2. The third insulating layer IL3 may cover the sixth gate electrode G6 and the second light blocking pattern BML2.

The third semiconductor pattern SP3 may be on the third insulating layer IL3. The third semiconductor pattern SP3 may include an oxide semiconductor including metal oxide. The oxide semiconductor may include metal oxide of zinc (Zn), indium (In), gallium (Ga), tin (Sn), and/or titanium (Ti) and/or may include metal such as zinc (Zn), indium (In), gallium (Ga), tin (Sn), and/or titanium (Ti) and a mixture of oxides thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), and/or zinc-tin oxide (ZTO). However, embodiments are not necessarily limited thereto.

The third semiconductor pattern SP3 may include a plurality of areas having different electrical properties depending on whether metal oxide is reduced or not. The area of the third semiconductor pattern SP3 where the metal oxide is reduced (hereinafter, referred to as the reduced area) may have a higher conductivity (e.g., electrical conductivity) than the area of the third semiconductor pattern SP3 where the metal oxide is not reduced (hereinafter, referred to as the non-reduced area). The reduced area may substantially serve as a source or drain of a transistor. The non-reduced area may substantially correspond to a channel (or, an active) of the transistor.

The third semiconductor pattern SP3 may include the third source S3, the third channel A3, and the third drain D3. The third source S3 and the third drain D3 may extend from the third channel A3 in opposite directions. For example, the third source S3 and the third drain D3 may be spaced apart from each other with the third channel A3 therebetween when viewed from above the plane.

The fourth insulating layer IL4 may be on the third insulating layer IL3. The fourth insulating layer IL4 may cover the third semiconductor pattern SP3.

The third gate electrode G3 may be on the fourth insulating layer IL4. The third gate electrode G3 may overlap the third channel A3. In an embodiment, the third gate electrode G3 may function as a mask in a process of doping the third semiconductor pattern SP3.

The third semiconductor pattern SP3 may overlap a portion of the second light blocking pattern BML2 provided under the third semiconductor pattern SP3. The portion of the second light blocking pattern BML2 that overlaps the third semiconductor pattern SP3 may serve as the gate of the third transistor T3 together with the third gate electrode G3. In embodiments, the third gate of the third transistor T3 may be formed double. Accordingly, the third gate of the third transistor T3 may have sufficient gate charges and may be switched at high speed. In embodiments, because the second light blocking pattern BML2 overlaps the third semiconductor pattern SP3, the third semiconductor pattern SP3 may be prevented from being damaged by light introduced from below the display panel DP (or a likelihood, occurrence, or degree of such damage may be reduced). However, the structure of the third transistor T3 is illustrated as an example, and embodiments are not limited thereto.

In embodiments, the fourth transistor T4 (refer to FIG. 5) described above may be a transistor having the same or substantially the same structure as the third transistor T3. For example, the semiconductor pattern of the fourth transistor T4 (refer to FIG. 5) may be formed from the second semiconductor pattern layer in the same or substantially the same manner as the third semiconductor pattern SP3, and the gate electrode of the fourth transistor T4 (refer to FIG. 5) may be formed from the same conductive pattern layer as the third gate electrode G3. However, embodiments are not necessarily limited thereto.

The third semiconductor pattern SP3 of the third transistor T3 and the sixth semiconductor pattern SP6 of the sixth transistor T6 may be on different layers. However, this is illustrated as an example, and the semiconductor patterns of all of the transistors included in the pixel drive circuit PDC (refer to FIG. 5) may be on the same layer.

The fifth insulating layer IL5 may be on the fourth insulating layer IL4. The fifth insulating layer IL5 may cover the third gate electrode G3.

The connecting electrodes CNE11 to CNE13 may be on the fifth insulating layer IL5. Each of the connecting electrodes CNE11 to CNE13 may include a metallic material such as titanium (Ti), aluminum (AI), molybdenum (Mo), and/or copper (Cu). The connecting electrodes CNE11 to CNE13 may include the first-first to first-third connecting electrodes CNE11 to CNE13. The first-first to first-third connecting electrodes CNE11 to CNE13 may be spaced apart from each other on the fifth insulating layer IL5. For convenience, FIG. 6 illustrates an example that the connecting electrodes CNE11 to CNE13, when viewed from above the plane, overlap contact holes CNT-11, CNT-12a, CNT-12b, and CNT-13 and have a flat upper surface. However, unlike those illustrated, the connecting electrodes CNE11 to CNE13 of an embodiment may be provided along the inner surfaces of contact holes CNT-11, CNT-12a, CNT-12b, and CNT-13.

The first-first connecting electrode CNE11 may be connected to the sixth drain D6 through the contact hole CNT-11 that penetrates the second to fifth insulating layers IL2 to IL5. The first-second connecting electrode CNE12 may be connected to the sixth source S6 through the contact hole CNT-12a that penetrates the second to fifth insulating layers IL2 to IL5.

The first-second connecting electrode CNE12 may extend on the plane and may overlap the third drain D3 of the third transistor T3. The first-second connecting electrode CNE12 may be connected to the third drain D3 through the contact hole CNT-12b that penetrates the fourth insulating layer IL4 and the fifth insulating layer IL5. Accordingly, the third semiconductor pattern SP3 of the third transistor T3 and the sixth semiconductor pattern SP6 of the sixth transistor T6 on different layers may be electrically connected with each other through the first-second connecting electrode CNE12. The first-third connecting electrode CNE13 may be connected to the third source S3 through the contact hole CNT-13 that penetrates the fourth insulating layer IL4 and the fifth insulating layer IL5.

The sixth insulating layer IL6 may be on the fifth insulating layer IL5. The sixth insulating layer IL6 may cover the first-first to first-third connecting electrodes CNE11 to CNE13. The sixth insulating layer IL6 may be an organic layer.

The upper connecting electrode CNE-T may be on the sixth insulating layer IL6. In embodiments, although not separately illustrated, some of the signal lines included in the display panel DP may be formed from a conductive pattern layer (e.g., an electrically conductive pattern layer) in the circuit layer DP_CL.

The upper connecting electrode CNE-T may be connected to the first-first connecting electrode CNE11 through an upper contact hole CNT-2 that penetrates the sixth insulating layer IL6. The upper connecting electrode CNE-T may be connected to the sixth drain D6 of the sixth transistor T6 through the first-first connecting electrode CNE11. However, embodiments are not limited thereto, and the upper connecting electrode CNE-T may be omitted, or an additional connecting electrode between the upper connecting electrode CNE-T and the first-first connecting electrode CNE11 may be further provided in the circuit layer DP_CL.

The seventh insulating layer IL7 may be on the sixth insulating layer IL6. The seventh insulating layer IL7 may cover the upper connecting electrode CNE-T. In embodiments, the seventh insulating layer IL7 may be an organic layer.

At least one selected from the sixth insulating layer IL6 and the seventh insulating layer IL7 may include an organic layer. The organic layer may provide a flat surface while covering particles existing on a surface of a layer provided under the organic layer or covering steps between components provided under the organic layer. In embodiments, the organic layer may alleviate stress between components on and under the organic layer.

The light emitting element layer DP_ED may be on the circuit layer DP_CL. The light emitting element layer DP_ED may include a pixel defining layer PDL and light emitting elements ED. Each of the light emitting elements ED may include a first electrode AE, an emissive layer EM, and a second electrode CE.

The light emitting elements ED may include an organic light emitting element, a quantum-dot light emitting element, a micro LED light emitting element, and/or a nano LED light emitting element. However, embodiments are not limited thereto, and the light emitting elements ED may include various suitable embodiments as long as depending on an electrical signal, light is generated or the amount of light is controlled.

Each of the light emitting elements ED may be electrically connected to the transistors of the corresponding pixel drive circuit PDC (refer to FIG. 5). FIG. 6 illustrates an example that each of the light emitting elements ED is electrically connected to the corresponding sixth transistor T6.

The first electrodes AE of the light emitting elements ED may be on the uppermost layer of the circuit layer DP_CL. For example, the first electrodes AE may be on the seventh insulating layer IL7. The first electrodes AE may be spaced apart from each other on the seventh insulating layer IL7. Each of the first electrodes AE may be connected to the corresponding upper connecting electrode CNE-T through a contact hole CNT-U that penetrates the seventh insulating layer IL7. The first electrode AE may be electrically connected to the sixth drain D6 through the corresponding upper connecting electrode CNE-T and the first-first connecting electrode CNE11.

The pixel defining layer PDL may be on the uppermost layer of the circuit layer DP_CL. For example, the pixel defining layer PDL may be on the seventh insulating layer IL7. Light emitting openings PX-OP that overlap the first electrodes AE and expose portions of the corresponding first electrodes AE may be defined in the pixel defining layer PDL. In this embodiment, the areas of the first electrodes AE exposed by the light emitting openings PX-OP may correspond to emissive areas PXA. For example, the display area DA (refer to FIG. 4) of the display panel DP may include the emissive areas PXA. The area where the pixel defining layer PDL is provided may correspond to a non-emissive area NPXA. When viewed from above the plane, the non-emissive area NPXA may be around (e.g., surround) the emissive areas PXA and may set the boundaries between the emissive areas PXA.

The pixel defining layer PDL may include a polymer resin. For example, the pixel defining layer PDL may include a polyacrylate-based resin and/or a polyimide-based resin. However, without being limited thereto, the pixel defining layer PDL may further include an inorganic material.

The pixel defining layer PDL may further include a light absorbing material. For example, the pixel defining layer PDL may include a black coloring agent such as a black dye and/or a black pigment. For example, the black coloring agent may include carbon black, metal such as chromium, and/or oxide thereof. However, embodiments are not necessarily limited thereto.

The emissive layers EM may be on the first electrodes AE. The emissive layers EM of the light emitting elements ED may correspond to the light emitting openings PX-OP and may be formed as emission patterns spaced apart from each other when viewed from above the plane. However, without being limited thereto, the emissive layers EM of the light emitting elements ED may be formed as an integrated film and may be formed as a common layer. The emissive layers EM may include an organic luminescent material and/or an inorganic luminescent material. For example, the emissive layers EM may include a fluorescent material, a phosphorescent material, a metal organic complex luminescent material, and/or a quantum dot. Each of the emissive layers EM may emit one selected from red light, green light, and blue light.

The second electrode CE may be on the emissive layers EM. The second electrode CE of the light emitting elements ED may be provided as an integrated common layer and may overlap the emissive areas PXA and the non-emissive area NPXA. The second electrode CE may be commonly provided in the pixels PX (refer to FIG. 4), and thus a common voltage may be provided to the pixels PX.

In embodiments, each of the light emitting elements ED may further include an emission control layer between the first electrode AE and the second electrode CE. For example, the emission control layer may include a hole control layer between the first electrode AE and the emissive layer EM and an electron control layer between the emissive layer EM and the second electrode CE. The hole control layer may include a hole injection layer, a hole transport layer, and/or an electron blocking layer, and the electron control layer may include an electron injection layer, an electron transport layer, and/or a hole blocking layer.

The encapsulation layer TFE may be on the light emitting element layer DP_ED. The encapsulation layer TFE may seal the light emitting elements ED. The encapsulation layer TFE may include at least one selected from an inorganic film and an organic film. In an embodiment, the encapsulation layer TFE may include inorganic films and an organic film between the inorganic films.

The inorganic film of the encapsulation layer TFE may protect the light emitting elements ED from moisture and/or oxygen. The inorganic film may include at least one selected from aluminum oxide, titanium oxide, silicon oxide, silicon nitride, silicon oxy nitride, zirconium oxide, and hafnium oxide. However, the material of the inorganic film is not limited thereto.

The organic film of the encapsulation layer TFE may protect the light emitting elements ED from foreign matter such as dust particles. The organic film may include an acrylic resin. However, the material of the organic film is not limited thereto.

The first drive voltage ELVDD (refer to FIG. 5) may be applied to the first electrode AE, and the second drive voltage ELVSS (refer to FIG. 5) may be applied to the second electrode CE. Holes and electrons injected into the emissive layer EM may be combined to form excitons, and the light emitting elements ED may emit light as the excitons transition to a ground state. The light emitting elements ED may emit light depending on electrical signals applied thereto so that the display panel DP may display an image through the display area DP_DA (refer to FIG. 4).

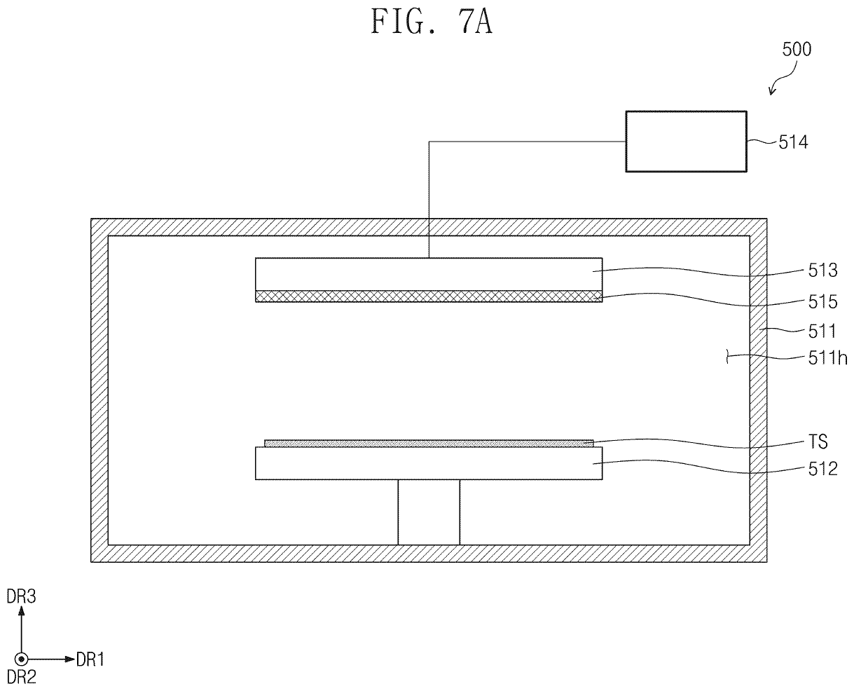

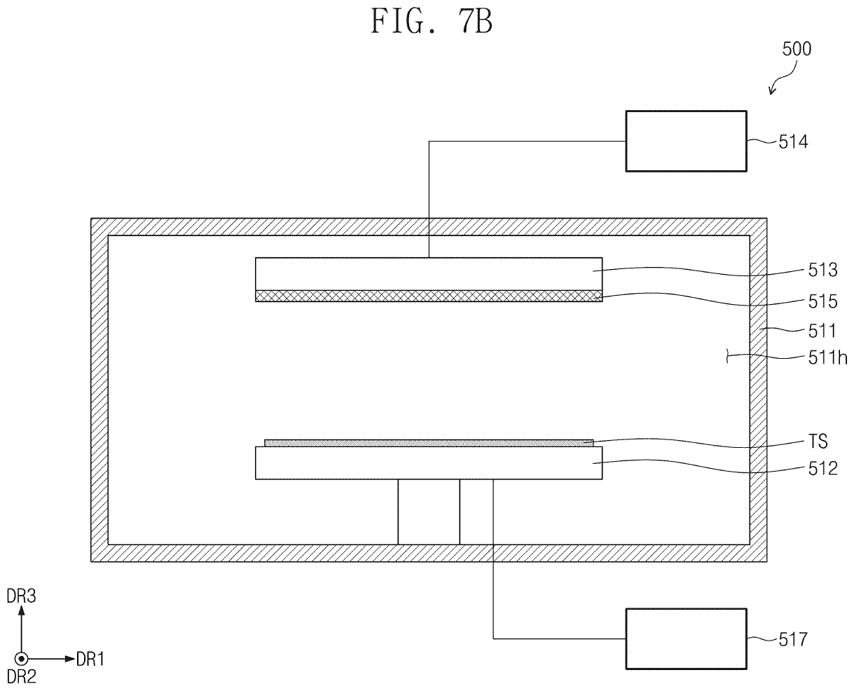

FIGS. 7A and 7B are views illustrating a sputtering device according to embodiments of the present disclosure.

Referring to FIG. 7A, the sputtering device 500 according to an embodiment of the present disclosure may be semiconductor equipment that performs a physical vapor deposition (PVD) process. The sputtering device 500 may be a device that performs a deposition process using high power impulse magnetron sputtering (HiPIMS).

The sputtering device 500 may include a deposition chamber 511, a support substrate 512, a plasma electrode 513, and a source target 515.

The deposition chamber 511 may provide a deposition space 511h. The deposition space 511h may be a space in which the deposition process is performed. The support substrate 512 may be provided in the deposition space 511h. A target substrate TS may be provided on the support substrate 512. The support substrate 512 may include a heater therein and may heat the target substrate TS.

The plasma electrode 513 may be provided in the deposition space 511h and may be provided over the support substrate 512. The sputtering device 500 may further include a power supply unit 514. The plasma electrode 513 may be connected to the power supply unit 514. The power supply unit 514 may instantaneously (or substantially instantaneously) supply high power to the plasma electrode 513 to form plasma in the deposition space 511h. The high power may be supplied in the form of a pulse. The power supply unit 514 may apply a high power of several MW to the plasma electrode 513 with, within, or for a set or certain period.

The source target 515 may be fixed to the lower surface of the plasma electrode 513. The source target 515 may include a source material (e.g., a metallic material) of a thin film (or, a thin metal film) deposited on the target substrate TS. For example, source particles (e.g., referred to as metal ions) may be formed from the source target 515 by the plasma formed in the deposition space 511h. The source particles may be deposited on the target substrate TS to form the thin metal film.

When plasma is generated after argon gas is injected into the deposition space 511h, argon ions (Art) are generated. The argon ions (Art) collide with the source target 515. When the kinetic energy of the colliding argon ions is greater than the bond energy of the source material, metal ions are emitted while the bonds in the source material are broken. When high power is instantaneously (or substantially instantaneously) applied to the plasma electrode 513, the kinetic energy of the argon ions may increase, and thus the straightness of the emitted metal ions may increase.

As illustrated in FIG. 7B, the support substrate 512 may be connected to a bias voltage supply unit 517. The bias voltage supply unit 517 may apply a bias voltage to the support substrate 512. For example, the bias voltage may be a negative voltage. However, the present disclosure is not limited thereto. When the metal ions are positive ions, the bias voltage may be a negative voltage, but when the metal ions are negative ions, the bias voltage may be a positive voltage.

When the bias voltage having a polarity opposite to that of the metal ions is applied to the support substrate 512, the straightness of the metal ions may be further increased.

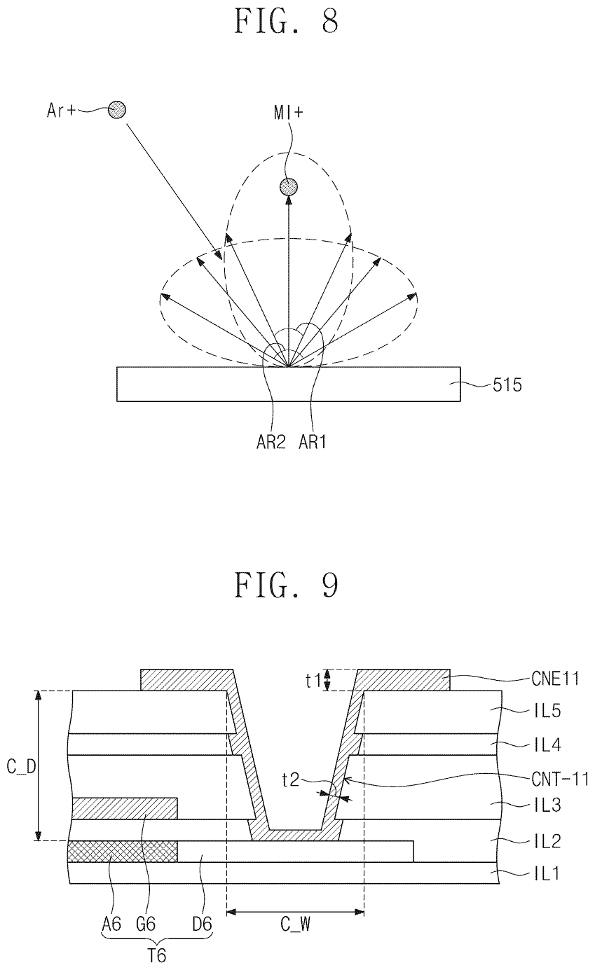

FIG. 8 is a view illustrating an emission form of metal ions according to an embodiment of the present disclosure.

As illustrated in FIGS. 7A and 8, the ion energy of the metallic material constituting the source target 515 may increase when the deposition process of the thin metal film is performed using the high power impulse magnetron sputtering (HiPIMS). In an embodiment of the present disclosure, the ion energy may range from 20 eV to 30 eV. When the ion energy increases, the straightness of a metal ion MI⁺ facing toward the target substrate TS may be enhanced. For example, the emission angle of the metal ion MI⁺ having the enhanced straightness may be in a first angle range AR1. However, when a DC voltage of several kW is applied to the plasma electrode 513, the emission angle of the metal ion MI⁺ may be in a second angle range AR2 wider than the first angle range AR1. For example, when the DC voltage of several kW is applied to the plasma electrode 513, the straightness of the metal ion MI⁺ may be decreased.

In embodiments, when the deposition process of the thin metal film is performed using the high power impulse magnetron sputtering (HiPIMS), the ionization rate of the metallic material may increase. In an embodiment of the present disclosure, the ionization rate of the metallic material may be 50% or more.

When the deposition process of the thin metal film is performed using the high power impulse magnetron sputtering (HiPIMS), the electron density of the thin metal film deposited on the target substrate TS may increase to 10¹⁹ m³ or more. For example, the thin metal film may be formed at a high density. Accordingly, the surface roughness of the thin metal film deposited on the target substrate TS may be improved.

FIG. 9 is an enlarged sectional view illustrating a contact hole portion of the display panel according to an embodiment of the present disclosure.

Referring to FIG. 9, the first-first connecting electrode CNE11 (hereinafter, referred to as the connecting electrode) may be connected to a portion (e.g., the sixth drain D6) of a transistor (e.g., the sixth transistor T6) through the contact hole CNT-11. The portion D6 of the transistor T6 may include poly silicon. However, the present disclosure is not limited thereto, and the portion D6 of the transistor T6 may include a metallic material. The connecting electrode CNE11 may include a metallic material. The metallic material may be aluminum, titanium, molybdenum, and/or copper.

The contact hole CNT-11 may be formed to penetrate the second to fifth insulating layers IL2 to IL5 and may expose the portion D6 of the transistor T6. The first-first connecting electrode CNE11 is on the upper surface of the fifth insulating layer IL5 and the side surfaces of the second to fifth insulating layers IL2 to IL5 that define the contact hole CNT-11.

Among the second to fifth insulating layers IL2 to IL5, at least one insulating layer (e.g., an electrically insulating layer, which may be referred to as a first intermediate insulating layer) may include silicon oxide, and at least one other insulating layer (e.g., an electrically insulating layer, which may be referred to as a second intermediate insulating layer) may include silicon nitride. In an embodiment of the present disclosure, the second insulating layer IL2 and the fourth insulating layer IL4 may include silicon oxide, and the third insulating layer IL3 and the fifth insulating layer IL5 may include silicon nitride. Each of the second insulating layer IL2 and the fourth insulating layer IL4 may be included in the first intermediate insulating layer, and each of the third insulating layer IL3 and the fifth insulating layer IL5 may be included in the second intermediate insulating layer. The first intermediate insulating layer and the second intermediate insulating layer may be alternately provided. A step may be provided between a first side surface of the first intermediate insulating layer IL2 and IL4 and a second side surface of the second intermediate insulating layer IL3 and IL5 that define the contact hole CNT-11.

In an embodiment of the present disclosure, the aspect ratio of the contact hole CNT-11 may be 0.8 or more. The aspect ratio of the contact hole CNT-11 represents the ratio of the depth C_D to the width C_W of the contact hole CNT-11. When two contact holes having the same or substantially the same width C_W are compared, the depth C_D of the contact hole having a larger aspect ratio is greater than the depth C_D of the contact hole having a smaller aspect ratio. As the aspect ratio of the contact hole CNT-11 increases, there may be a problem that the connecting electrode CNE11 formed within the contact hole CNT-11 is disconnected. In embodiments, when the aspect ratio of the contact hole CNT-11 increases and the step is formed between the side surfaces that define the contact hole CNT-11, the disconnection of the connecting electrode CNE11 may increase.

In an embodiment of the present disclosure, the connecting electrode CNE11 is formed from a thin metal film deposited through the sputtering device illustrated in FIGS. 7A and 7B. For example, the connecting electrode CNE11 is formed by making a thin metal film deposited using HiPIMS subject to patterning. When the thin metal film is deposited using the HiPIMS, the straightness of the metal ion MI⁺ (refer to FIG. 8) may be enhanced, and thus the thin metal film may be stably deposited within the contact hole CNT-11. For example, even though the aspect ratio of the contact hole CNT-11 increases and the step is formed between the side surfaces that define the contact hole CNT-11, disconnection of the connecting electrode CNE11 may be prevented (or a likelihood, occurrence, or degree thereof may be reduced) when the thin metal film is deposited using the HiPIMS.

When the thin metal film is deposited using the HiPIMS, the step coverage of the connecting electrode CNE11 may be improved to 20% or more. The step coverage of the connecting electrode CNE11 is defined as the ratio of the thickness t2 (hereinafter, referred to as the second thickness) of the connecting electrode CNE11 on the side surfaces of the second to fifth insulating layers IL2 to IL5 that define the contact hole CNT-11 to the thickness t1 (hereinafter, referred to as the first thickness) of the connecting electrode CNE11 on the upper surface of the fifth insulating layer IL5. For example, the first thickness t1 is the thickness of an upper surface portion of the connecting electrode CNE11, and the second thickness t2 is the thickness of a lateral surface portion of the connecting electrode CNE11.

When the thin metal film is deposited using the HiPIMS, the step coverage of the connecting electrode CNE11 may be secured to 20% or more even in a structure in which the aspect ratio of the contact hole CNT-11 is increased to 0.8 or more. The lateral surface portion of the connecting electrode CNE11 within the contact hole CNT-11 may be continuously formed without disconnection, and thus the process reliability of the display panel DP may be improved.

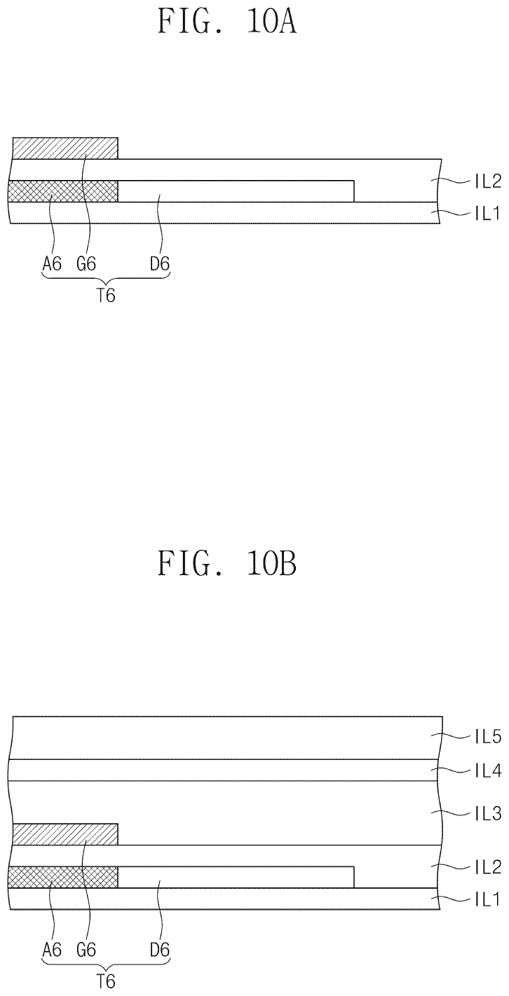

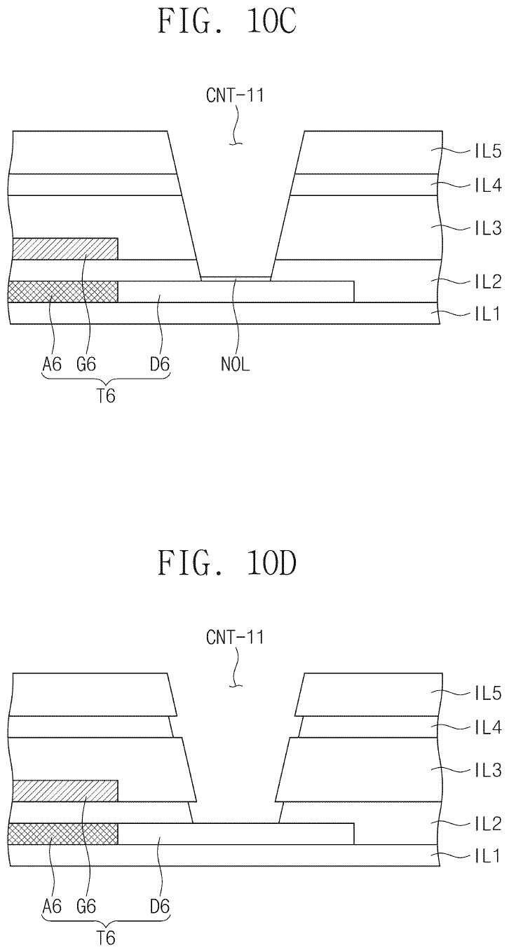

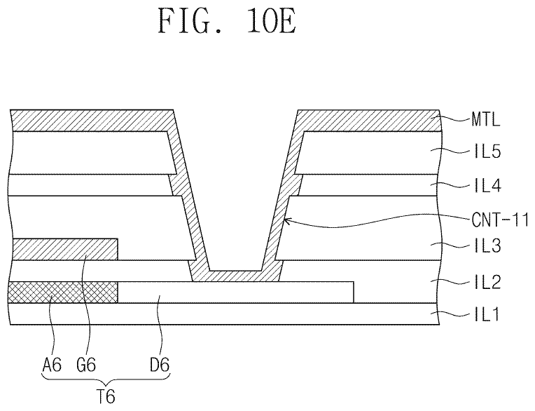

FIGS. 10A to 10E are cross-sectional views illustrating a process of manufacturing the display panel according to an embodiment of the present disclosure.

Referring to FIGS. 6 and 10A to 10E, the manufacturing process of the display panel includes forming the circuit layer DP_CL on the base layer BL and forming the light emitting element ED disposed on the circuit layer DP_CL.

The forming the circuit layer DP_CL includes forming the transistors T3 and T6 on the base layer BL, forming, on the transistors T3 and T6, the insulating layers IL2 to IL5 in which the contact holes CNT-11, CNT-12a, CNT12-b, and CNT-13 exposing portions of the transistors T3 and T6 are defined, and forming the connecting electrodes CNE11, CNE12, CNE13 electrically connected with the transistors T3 and T6 through the contact holes CNT-11, CNT-12a, CNT12-b, and CNT-13.

Referring to FIGS. 10A and 10B, the transistor T6 is formed on the base layer BL, and the third to fifth insulating layers IL3 to IL5 are sequentially stacked on the transistor T6.

Among the second to fifth insulating layers IL2 to IL5, at least one insulating layer (e.g., an electrically insulating layer, which may be referred to as the first intermediate insulating layer) may include silicon oxide, and at least one other insulating layer (e.g., an electrically insulating layer, which may be referred to as the second intermediate insulating layer) may include silicon nitride. In an embodiment of the present disclosure, the second insulating layer IL2 and the fourth insulating layer IL4 may include silicon oxide, and the third insulating layer IL3 and the fifth insulating layer IL5 may include silicon nitride. Each of the second insulating layer IL2 and the fourth insulating layer IL4 may be included in the first intermediate insulating layer, and each of the third insulating layer IL3 and the fifth insulating layer IL5 may be included in the second intermediate insulating layer. The first intermediate insulating layer and the second intermediate insulating layer may be alternately provided.

Referring to FIG. 10C, the contact hole CNT-11 may be formed by removing portions of the second to fifth insulating layers IL2 to IL5. The contact hole CNT-11 may expose a portion (e.g., the sixth drain D6) of the transistor T6. In an embodiment of the present disclosure, the aspect ratio of the contact hole CNT-11 may be 0.8 or more. A native oxide film NOL may be formed on a portion of the transistor T6 in the process of forming the contact hole.

Referring to FIGS. 10C and 10D, the native oxide film NOL may be removed through HF vapor cleaning. The HF vapor cleaning is a method of removing the native oxide film NOL using vapor generated by evaporating an HF cleaning solution. During the HF vapor cleaning, the side surfaces of the second to fifth insulating layers IL2 to IL5 that define the contact hole CNT-11 may be damaged, and as a result, a step may be formed between the side surfaces of the second to fifth insulating layers IL2 to IL5.

Referring to FIG. 10E, a thin metal film MTL may be deposited on the fifth insulating layer IL5 using high power impulse magnetron sputtering (HiPIMS). The thin metal film MTL is formed utilizing the sputtering device illustrated in FIGS. 7A and 7B. The deposition process of the thin metal film MTL includes placing the target substrate TS having the contact hole CNT-11 defined therein on the support substrate 512 provided in the deposition chamber 511 that provides the deposition space 511h, instantaneously (or substantially instantaneously) supplying high power to the plasma electrode 513 facing the support substrate 512, and forming the thin metal film MTL on the target substrate TS.

When the thin metal film MTL is deposited using the HiPIMS as described above, the straightness of the metal ion MI⁺ (refer to FIG. 8) may be enhanced, and thus the thin metal film MTL may be stably deposited within the contact hole CNT-11. For example, even though the aspect ratio of the contact hole CNT-11 increases and the step is formed between the side surfaces that define the contact hole CNT-11, disconnection of the thin metal film MTL may be prevented (or a likelihood, occurrence, or degree thereof may be reduced) when the thin metal film MTL is deposited using the HiPIMS.

When the thin metal film MTL is deposited using the HiPIMS, the step coverage of the thin metal film MTL may be improved to 20% or more. The ratio of the thickness t2 (refer to FIG. 9) of a lateral surface portion of the thin metal film MTL to the thickness t1 (refer to FIG. 9) of an upper surface portion of the thin metal film MTL may be 20% or more. When the thin metal film MTL is deposited using the HiPIMS, the step coverage of the thin metal film MTL may be secured to 20% or more even in a structure in which the aspect ratio of the contact hole CNT-11 is increased to 0.8 or more. The lateral surface portion of the thin metal film MTL within the contact hole CNT-11 may be continuously formed without disconnection, and thus the process reliability of the display panel DP may be improved.

Thereafter, as illustrated in FIG. 9, the connecting electrode CNE11 may be formed through a patterning process of the thin metal film MTL.

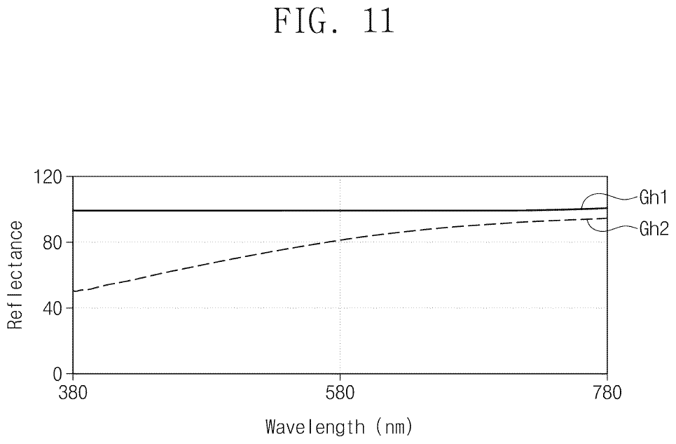

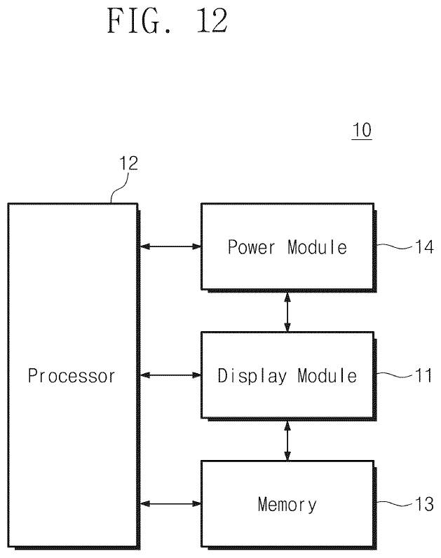

FIG. 11 is a graph depicting the reflectance of a thin metal film according to an embodiment of the present disclosure. The first graph Gh1 depicts the reflectance of a thin metal film formed according to the present disclosure, and the second graph Gh2 depicts the reflectance of a thin metal film formed according to a comparative example.

Referring to FIGS. 10E and 11, when the deposition process of the thin metal film MTL is performed using the HiPIMS, the ion energy of the metallic material constituting the source target 515 (refer to FIG. 7A) may increase. When the metal ions with high energy are incident to the target substrate TS (refer to FIG. 7A), the electron density of the thin metal film MTL may increase to 10¹⁹ m³ or more. For example, the thin metal film MTL may be formed in a dense structure and may have a low surface roughness. As the surface roughness of the thin metal film MTL increases, the reflectance of the thin metal film MTL may increase. For example, the thin metal film MTL according to the present disclosure may have a reflectance of 80% or more in the wavelength range of 380 nm to 780 nm. However, when the thin metal film is formed by applying a DC voltage of several kW to the plasma electrode 513 (refer to FIG. 7A), the surface roughness of the thin metal film may increase, and the reflectance of the thin metal film may decrease. For example, the thin metal film according to the comparative example may have a reflectance of 80% or less in the wavelength range of 380 nm to 580 nm and may have a lower reflectance even in the wavelength range of 580 nm to 780 nm than the thin metal film MTL according to the present disclosure.

The display module according to an embodiment may be applied to various suitable electronic devices. An electronic device according to an embodiment may include the display module described above and may further include a module or device having other additional functions in addition to a display device.

FIG. 12 is a block diagram of the electronic device according to an embodiment of the present disclosure.

Referring to FIG. 12, the electronic device 10 according to an embodiment may include a display module 11, a processor 12, a memory 13, and a power module 14.

The processor 12 may control operation of the display module 11 and may include at least one selected from a central processing unit (CPU), an application processor (AP), a graphic processing unit (GPU), a communication processor (CP), an image signal processor (ISP), and a controller.

Data information required or utilized for operation of the processor 12 or the display module 11 may be stored in the memory 13. When the processor 12 executes an application stored in the memory 13, an image data signal and/or an input control signal may be transferred to the display module 11, and the display module 11 may process the provided signal and may output image information through a display screen.

The power module 14 may include a power supply module, such as a power adaptor and/or a battery device, and a power conversion module that converts power supplied by the power supply module and generates power required or utilized for operation of the electronic device 10.

At least one of the components of the electronic device 10 described above may be included in the display module according to the embodiments described above. In embodiments, some of the separate modules functionally included in one module may be included in the display module, and the other separate modules may be provided separately from the display module. For example, the display module 11 may be included in the display device, and the processor 12, the memory 13, and the power module 14 may be provided in the form of other devices within the electronic device 10 rather than the display device.

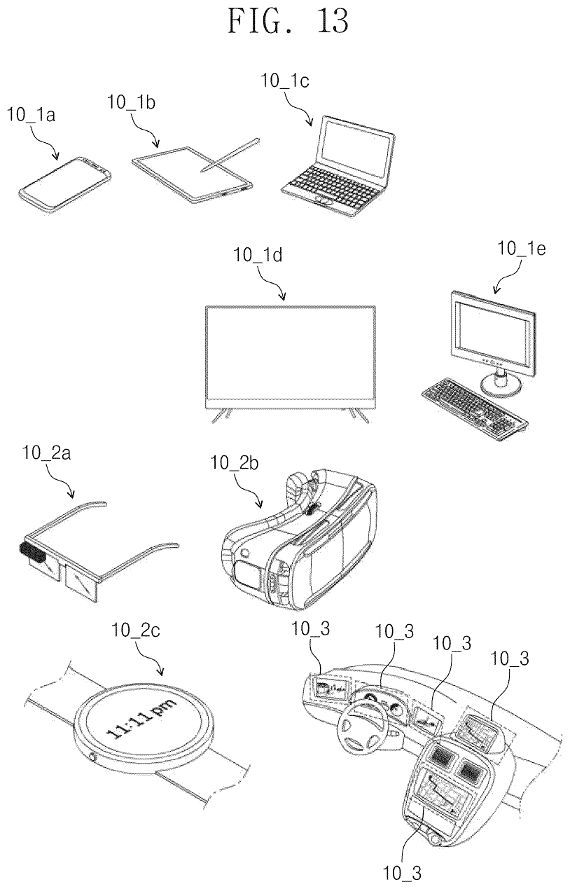

FIG. 13 illustrates schematic views of electronic devices according to various embodiments.

Referring to FIG. 13, the electronic devices according to the various embodiments, to which the display module is applied, may include not only an electronic device to display an image, such as a smart phone 10_1a, a tablet PC 10_1b, a laptop computer 10_1c, a TV 10_1d, or a desk monitor 10_1e, but also a wearable electronic device, such as smart glasses 10_2a, a head mounted display 10_2b, and/or a smart watch 10_2c, and a vehicle electronic device 10_3, such as a center information display (CID) and/or a room mirror display provided on an instrument panel, a center fascia, and/or a dashboard of a vehicle.

According to embodiments the present disclosure, even though the aspect ratio of the contact hole increases and the step is formed on the surface that defines the contact hole, the thin metal film may be stably deposited within the contact hole of the target substrate when the straightness of the ions of the metallic material is enhanced. Accordingly, the thin metal film may be continuously formed within the contact hole of the target substrate without disconnection, and thus the process reliability of the display panel may be improved.

While the subject matter of the present disclosure has been described with reference to embodiments thereof, it will be apparent to those of ordinary skill in the art that various suitable changes and modifications may be made thereto without departing from the spirit and scope of the present disclosure as set forth in the following claims, and equivalents thereof.

What is claimed is:

1. A display panel comprising:
a base layer;
a circuit layer on the base layer; and
a light emitting element on the circuit layer,
wherein the circuit layer comprises:
a transistor on the base layer;
an insulating layer on the transistor, the insulating layer having a contact hole defined therein to expose a portion of the transistor; and
a connecting electrode electrically connected with the transistor through the contact hole,
wherein an aspect ratio of the contact hole defined as a ratio of a depth of the contact hole to a width of the contact hole is 0.8 or more,
wherein the connecting electrode comprises a lateral surface portion on a side surface of the insulating layer configured to define the contact hole and an upper surface portion on the insulating layer, and
wherein a step coverage defined as a ratio of a thickness of the lateral surface portion to a thickness of the upper surface portion is 20% or more.

2. The display panel of claim 1, wherein the insulating layer has a structure in which a plurality of insulating layers are sequentially stacked,
wherein at least one first intermediate insulating layer among the plurality of insulating layers includes silicon oxide, and
wherein at least one second intermediate insulating layer among the plurality of insulating layers includes silicon nitride.

3. The display panel of claim 2, wherein a step is provided between a first side surface of the first intermediate insulating layer and a second side surface of the second intermediate insulating layer configured to define the contact hole.

4. The display panel of claim 1, wherein the transistor comprises a semiconductor pattern, and
wherein the contact hole exposes a portion of the semiconductor pattern.

5. The display panel of claim 4, wherein the semiconductor pattern comprises poly silicon.

6. A method for manufacturing a display panel, the method comprising:
forming a circuit layer on a base layer; and
forming a light emitting element disposed on the circuit layer,
wherein the forming the circuit layer comprises:
forming a transistor on the base layer;
forming, on the transistor, an insulating layer having a contact hole defined therein to expose a portion of the transistor; and
forming a connecting electrode electrically connected with the transistor through the contact hole,
wherein an aspect ratio of the contact hole defined as a ratio of a depth of the contact hole to a width of the contact hole is 0.8 or more,
wherein the connecting electrode comprises a lateral surface portion on a side surface of the insulating layer configured to define the contact hole and an upper surface portion on the insulating layer, and
wherein a step coverage defined as a ratio of a thickness of the lateral surface portion to a thickness of the upper surface portion is 20% or more.

7. The method of claim 6, wherein the forming the connecting electrode comprises:
placing a target substrate having the contact hole defined therein on a support substrate provided in a deposition chamber configured to provide a deposition space;
supplying high power to a plasma electrode provided in the deposition space and configured to face the support substrate;
forming a thin metal film on the target substrate; and
forming the connecting electrode by making the thin metal film subject to patterning.

8. The method of claim 7, wherein a high power of several MW is applied to the plasma electrode with a certain period in the supplying the high power to the plasma electrode.

9. The method of claim 7, wherein the forming the connecting electrode further comprises applying a bias voltage to the support substrate.

10. The method of claim 9, wherein the bias voltage is a negative voltage.

11. The method of claim 6, wherein the forming the insulating layer comprises:
sequentially stacking a plurality of insulating layers;
forming the contact hole by removing portions of the plurality of insulating layers; and
removing a native oxide film formed in the forming the contact hole.

12. The method of claim 11, wherein at least one first intermediate insulating layer among the plurality of insulating layers comprises silicon oxide, and
wherein at least one second intermediate insulating layer among the plurality of insulating layers comprises silicon nitride.

13. The method of claim 12, wherein after the removing the native oxide film, a step is provided between a first side surface of the first intermediate insulating layer and a second side surface of the second intermediate insulating layer configured to define the contact hole.

14. The method of claim 7, wherein the thin metal film has an electron density of 10¹⁹ m³ or more.

15. The method of claim 6, wherein the transistor comprises a semiconductor pattern, and
wherein the contact hole exposes a portion of the semiconductor pattern.

16. The method of claim 15, wherein the semiconductor pattern comprises poly silicon.

17. A sputtering device for forming a thin metal film on a target substrate having a contact hole defined therein, the sputtering device comprising:
a deposition chamber configured to provide a deposition space;
a support substrate configured to support the target substrate within the deposition space;
a plasma electrode configured to face the target substrate within the deposition space;
a source target fixed to the plasma electrode; and
a power supply unit configured to supply high power to the plasma electrode,
wherein an aspect ratio of the contact hole defined as a ratio of a depth of the contact hole to a width of the contact hole is 0.8 or more,
wherein the thin metal film comprises a lateral surface portion on a side surface of an insulating layer configured to define the contact hole and an upper surface portion on the insulating layer, and
wherein a step coverage defined as a ratio of a thickness of the lateral surface portion to a thickness of the upper surface portion is 20% or more.

18. The sputtering device of claim 17, wherein the power supply unit applies a high power of several MW to the plasma electrode with a certain period.

19. The sputtering device of claim 17, further comprising:
a bias voltage supply unit configured to apply a bias voltage to the support substrate.

20. An electronic device comprising the display panel of claim 1, wherein the electronic device is a television, a monitor, a billboard, a tablet computer, a car navigation unit, a personal computer, a notebook computer, a personal digital terminal, a game machine, a smart phone, a camera, or a wearable device.
